(19) United States
(12) Patent Application Publication
(10) Pub. No.: US 2026/0242885 A1
(43) Pub. Date: Aug. 20, 2026

(54) CARTRIDGE CASE ANNEALER WITH DATA ANALYSIS

(71) Applicant: Derek Sinz, LEXINGTON, AL (US)

(72) Inventor: Derek Sinz, LEXINGTON, AL (US)

(73) Assignee: KNOWLEDGEABLE HOLDINGS LLC, SHERIDAN, WY (US)

(21) Appl. No.: 19/640,994

(22) Filed: Apr. 7, 2026

Related U.S. Application Data
(62) Division of application No. 18/470,246, filed on Sep. 19, 2023.
(60) Provisional application No. 63/376,266, filed on Sep. 19, 2022.

(51) Int. Cl. C21D 1/26; F42B 33/00; H01F 27/24; H05B 6/06; H05B 6/36

(52) U.S. Cl. CPC C21D 1/26; F42B 33/00; H01F 27/24; H05B 6/06; H05B 6/365

(57) ABSTRACT

An ammunition cartridge case annealing system captures data which varies based on physical properties of the cartridge case. Data is gathered before, during, and after annealing from an induction coil and from sensors. Data may be analyzed to determine the physical properties of cartridge cases. A machine sorts cartridge cases by their physical properties.

### CROSS-REFERENCE TO RELATED APPLICATIONS

This application is a divisional of U.S. patent application Ser. No. 18/470,246, filed Sep. 19, 2023, which claims the benefit of U.S. Provisional Application No. 63/376,266, filed Sep. 19, 2022, each of which is incorporated herein by reference in its entirety.

### REFERENCE TO RELATED PATENTS

U.S. Patents

| Patent | Kind | | |
|---|---|---|---|
| Number | Code | Publ. Date | Patentee |
| 2,430,005 | A | 1947 Nov. 4 | Denneen, Francis S. et al. |
| 2,783,384 | A | 1957 Feb. 26 | Royer, George H. et al. |
| 2,907,858 | A | 1959 Oct. 6 | Distler, Edward C. |
| 2,937,017 | A | 1960 May 17 | Carbo, Edward J. |
| 3,005,894 | A | 1961 Oct. 24 | Carbo, Edward J. et al. |
| 3,663,782 | A | 1972 May 16 | Emerson, William A. |
| 3,743,808 | A | 1973 Jul. 3 | Kasper, Robert J. |
| 3,746,825 | A | 1973 Jul. 17 | Pfaffmann, George D. |
| 3,829,650 | A | 1974 Aug. 13 | Armstrong, Robert G. |
| 4,059,795 | A | 1977 Nov. 22 | Mordwinkin, George |
| 4,230,987 | A | 1980 Oct. 28 | Mordwinkin, George |
| 4,427,463 | A | 1984 Jan. 24 | Spies, Klaus |
| 4,618,125 | A | 1986 Oct. 21 | Balzer, Norbert R. |
| 4,816,633 | A | 1989 Mar. 28 | Mucha, George M. et al. |
| 7,015,439 | B1 | 2006 Mar. 21 | Thomas, Jeffrey R. et al. |
| 8,038,931 | B1 | 2011 Oct. 18 | Thomas, Jeffrey R. et al. |
| 9,250,050 | B2 | 2016 Feb. 2 | Nuetzman, Steven E. et al. |
| 10,876,191 | B2 | 2020 Dec. 29 | Findlay, Alexander et al. |
| 11,209,375 | B2 | 2021 Dec. 28 | Findlay, Alexander et al. |

Foreign Patent Documents

| Patent | Cntry | Kind | | |
|---|---|---|---|---|
| Number | Code | Code | Date | Name |
| 2023122336 | WO | A1 | 2023 Jun. 29 | Ryland, Graham et. al. |

### REFERENCE TO RELATED APPLICATIONS

U.S Patent Application Publications

| | Kind | | |
|---|---|---|---|
| Patent Appl. Nr. | Code | Publ. Date | Patentee |
| 20060016524 | A1 | 2006 Jan. 26 | Scharch, Daniel J. |
| 20120145288 | A1 | 2012 Jun. 14 | Stratford, Lee |
| 20140144903 | A1 | 2014 May 29 | Findlay, Alexander et. al. |
| 20190227013 | A1 | 2019 Jul. 25 | Findlay, Alexander et al. |
| 20210251055 | A1 | 2021 Aug. 12 | Spitans, Sergejs et al. |

### NON-PATENT CITATIONS

Title:“Automatic Casefeeder for the Dillon 550B Loading Press” Print date: 2006 Feb. 5
Site name: Gunblast.com URL: https://gunblast.com/Dillon-Casefeeder.htm
Title: “Royer oscillator induction heater”, Print Date: 2011 Aug. 2, Site name: YouTube.com, URL: https://www.youtube.com/watch?v=0019qDlfOm0
Title: “case annealing machine—induction” Print date: 2014 Feb. 13 Site name: YouTube
URL: https://www.youtube.com/watch?v=EGfGV8xrfak
Title: “The GinaErick induction annealer” Print date: 2016 Aug. 29 Site name: YouTube
URL: https://www.youtube.com/watch?v=57RL5v54FhM
Title: “Annealing SAM podajnik (feeder)” Print date: 2019 Feb. 17 Site name: YouTube
URL: https://www.youtube.com/watch?v=xMPI-bmsDw8

### BACKGROUND OF THE INVENTION

### The Necessity of Cartridge Case Annealing

When an ammunition cartridge is fired the high pressure within the cartridge slams it against the chamber of the firearm, causing it to become harder and less malleable. While hardness may be a desirable property in the lower portion or “base” of an ammunition cartridge case it is undesirable in the upper portion of the cartridge or “neck” which holds the bullet. Neck hardness interferes with the case expansion necessary to release the bullet and seal against the firearm chamber. It may cause the neck to split during use, releasing hot gasses and debris.

Ammunition cartridge cases are annealed before reloading in order to soften the neck and relieve stress areas in the neck. When annealing a cartridge case it is important to ensure that only the neck of the cartridge case becomes annealed. The base of a cartridge case must not become annealed because the loss of strength would lead to a severe failure of the cartridge during use, possibly resulting in damage to the firearm and personal injury.

Induction annealers for cartridge cases use alternating magnetic flux to induce current into the neck of a cartridge case. As the current flows through the resistance of the cartridge case it generates heat. The heat changes the crystalline structure of the metal, causing it to become annealed.

### Types of Cartridge Case Annealers

There are two standard methods of generating the magnetic flux required to heat a cartridge case neck without heating the base. The first employs an induction coil that encompasses the neck but not the base. The second employs a magnetic core material such as ferrite or laminated iron which conducts flux from the induction coil into the relatively small neck area. When a magnetic core is used for this purpose it is commonly called a flux concentrator. In this disclosure the term magnetic core is used for clarity.

### Drawbacks of Work Coil Annealers

Induction annealers in which a coil encompasses the item refer to the induction coil as a work coil. This type of annealer typically suffers from high levels of power loss in the coil. This is because a small induction coil without a magnetic core does not generate much flux per unit of amperage. Therefore, high amperage is required to generate the flux levels needed. The high levels of amperage generate large resistive losses in the metal of the induction coil, which in turn heats the induction coil itself. Additionally, any heat convected or radiated from the case also heats the coil. This almost always necessitates the use of a liquid cooled hollow tube as the conductor.

Unfortunately the use of a large hollow tube rather than multiple strands of small diameter wires further increases losses. This is due to factors such as the proximity effect and the skin effect which force all of the current flowing through the large hollow tube into a small cross sectional area. As such, induction annealers which do not use a magnetic core tend to require high power levels and liquid cooling which increases their overall cost and requires special manufacturing considerations.

### Drawbacks of Magnetic Cores

Induction annealers which use a magnetic core suffer from a different set of problems related to the physical size of the core, its nonlinear temperature characteristics, and its cooling requirements. Since the function of a magnetic core in this application is to conduct the magnetic flux into the small neck area, almost all of the flux produced by the induction coil flows through the magnetic core. This heats the magnetic core itself through induction heating, which in turn changes the magnetic permeability and loss factors of the magnetic core.

Cooling a magnetic core is not a trivial consideration because most core materials do not easily conduct heat. Therefore the most common method of reducing core loss is to increase the core size in an effort to reduce the total heat. Larger magnetic cores conduct magnetic flux over a larger surface area which reduces losses by lowering the concentration of magnetic flux in the core. Unfortunately large magnetic cores are expensive and are more difficult to cool than smaller cores. Although a larger core may generate less heat, magnetic materials tend to have a high specific heat and hold a high amount of thermal energy. This results in an inner core area which is at a higher temperature than the outer core area. Due to this temperature gradient, the magnetic characteristics of the core are difficult to predict from the surface temperature. The overall result is inconsistent power delivery, inconsistent inductance, and inconsistent loss, all of which may need to be compensated for in software or with additional sensors.

### Field of the Invention

The present disclosure relates to the induction annealing of ammunition cartridge cases, more specifically the induction annealing of ammunition cartridge cases for reloading.

### Description of the Prior Art

Most of the early induction annealers were built for industrial applications but advances in technology have enabled the development of consumer products. Around 2002, Vladimiro Mazzilli's modification of the oscillator claimed by George Royer in 1957 patent U.S. 2783384A helped to popularize the use of inexpensive oscillator devices which were powerful enough for induction annealing. A variant of this design which uses two inductors is commonly called a ZVS driver, even though there are many circuits which utilize zero voltage switching (ZVS).

Around 2010 the company Fluxeon introduced an induction annealer called Roy which also used an oscillator similar to the Royer oscillator. The schematics of Roy were made publicly available. Some implementations of Roy used a magnetic core as a flux concentrator.

In 2014 the company AMP Annealing Limited was granted U.S. patent 20140144903 which disclosed a cartridge case annealer that used a magnetic core wound with an induction coil and held the neck of cartridge cases inside a gap in the magnetic core.

Around 2016 detailed plans were released for a generic induction annealer for cartridge cases called GinaErick. This design used a ZVS driver to power an induction coil that encompassed the cartridge case, and also placed a trapdoor below the induction coil to release the cartridge case when annealing was completed.

Around 2017 an induction annealer for cartridge cases called “Smart Annealing Machine” was released. This design also used a trapdoor to release a cartridge case from a coil encompassing the case after annealing was completed. The platform was adjustable in height to accommodate a variety of cases.

### Limitations of Cartridge Case Annealers from Prior Art

I have found that annealers with work coils tend to be large and complex due to the need for a liquid cooled coil. This complexity makes such annealers expensive as a result, and the power consumption tends to be high. The few work coil annealer designs which are not liquid cooled do not have the consistency of operation required for high precision shooting or the capability for extended operation required by competition shooters and high volume reloaders.

I have also found the magnetic field generated by annealers with a magnetic core tends to impart problematic physical force upon a cartridge case during annealing. Specifically, a magnetic core tends to physically push the cartridge case out of its magnetic field. This makes securing the cartridge in a case holder a requirement. The requirement of using a case holder to anneal cartridges makes the process slow and mechanically complicated to automate. Simply dropping a cartridge case into an annealing chamber is not an option when a case holder is required.

Further I have found that induction annealers for cartridge cases do not provide the customer with useful information about the annealing process or about the physical properties of the case. It is a known fact that cartridge cases suffer from physical inconsistencies that affect accuracy, yet induction annealers do not provide data that might indicate these inconsistencies. Also, after a given number of reloading cycles cartridge cases tend to split or suffer excessive wear that leads to failure, but induction annealers to not detect it.

In the 1977 and 1980 U.S. Pat. Nos. 4,059,795 and 4,230,987, Mordwinkin disclosed a method for sensing the composition of metal objects by inducing eddy currents into them using a square wave. The Mucha U.S. Pat. No. 4,816,633 of 1989 used changes in annealing data to detect inconsistencies in heat treatment of camshafts. Annealing data has also been used to detect a significant change in a cartridge case being annealed, such as melting. However, annealing data has not been used to detect the subtle physical differences between cartridge cases, and annealing data has not been made data available to the user. It is unfortunate that in the field of cartridge case annealing, data has not been processed in a way that would uncover inconsistency or damage to cartridge cases.

### Summary

It should be evident from the aforementioned discussion that there is a need for a method, apparatus, and system which overcomes the limitations of the prior art.

An embodiment shows a method for annealing an ammunition cartridge case. A cartridge case is placed onto a movable slide so that its neck is within an annealing chamber, an alternating magnetic flux passes through its neck to heat it, and the slide is moved to release it. Data may be gathered throughout the process from the induction head, and may also be gathered from other sensors. Data may be used to sort the cartridge case into bins according to pass/fail standards or other metrics. Cartridge cases may also be sorted into bins at the discretion of the user.

Another embodiment details an apparatus for annealing cartridge cases. Two magnetic cores are placed around a central axis. Both may deliver a magnetic field to the neck of a cartridge case simultaneously, creating a centralizing magnetic force. An embodiment of the apparatus operates at less than half the operating temperature of traditional magnetic core designs, and is therefore capable of providing improved data.

Another embodiment shows a system for annealing an ammunition cartridge case. It includes an induction head for heating a cartridge case, a controllable power supply for powering the induction head, a data unit for collecting data, and a hardware I/O unit for transferring data to a computer. Modules of the system may be added or withdrawn. The system may include an automation machine which automatically transfers cartridges from a case feeder to the induction head, anneals, and sorts them into separate bins. The system may include a servo controller. The system may be user programmable so that processes, criteria, and analysis methods can be modified.

### Advantages

Aspects of some embodiments have advantages over prior art even when not incorporated within the embodiments disclosed, and all aspects should be considered novel independently of any particular embodiment.

Some advantages of embodiments may include the ability to anneal for extended periods of time without a loss in precision, and without the use of a liquid cooling system. Other advantages of some embodiments may include operation without the use of a cartridge case holder or custom adapters for each cartridge case.

Another advantage of some embodiments is the ability to collect, store, and transfer data to a computer. Another advantage is that data can be used to detect damaged cartridge cases, or to detect differences within cartridge cases. Some embodiments allow for cartridge cases to be sorted into different bins based on standards or at the discretion of the user.

Yet another advantage of some embodiments is the freedom of the user to define processes and/or attach servo motors which can be controlled to meet their individual reloading needs.

Other advantages of embodiments and of aspects of embodiments will become apparent from reading the description and viewing the corresponding drawings.

### BRIEF DESCRIPTION OF DRAWINGS

FIG. 1a shows an exemplary block diagram of modules that may form a system for annealing cartridge cases.

FIG. 1b shows an embodiment of an apparatus for annealing cartridge cases.

FIG. 1c shows an embodiment of an apparatus for annealing cartridge cases connected to a computer.

FIG. 1d shows an embodiment of an apparatus for annealing cartridge cases with an automation machine attached.

FIG. 2a shows an embodiment of an induction head.

FIG. 2b shows an embodiment of a split hinged bobbin.

FIG. 2c shows an embodiment of a manufacturing jig.

FIG. 2d shows an embodiment of an airflow barrier.

FIG. 2e shows an embodiment of two airflow barriers in a case annealer;

FIG. 3a shows the intensity of the alternating magnetic flux of an exemplary induction head during operation.

FIG. 3b shows the force applied by an exemplary induction head to a cartridge case during operation.

FIG. 3c shows a cartridge case centered in an exemplary annealing chamber during operation.

FIG. 4a illustrates a comparative model of core center temperature in an exemplary induction head during operation.

FIG. 4b illustrates the comparative cooling advantages of an exemplary induction head during operation.

FIGS. 5a and 5b illustrate how a low head temperature improves data collection during annealing.

FIGS. 5c and 5d illustrate how a low temperature gradient improves data collection during annealing.

FIG. 6a shows an embodiment of an induction head that uses multiple magnetic cores.

FIG. 6b shows an embodiment of an induction head that uses slit magnetic cores.

FIG. 6c shows an embodiment of an induction head with contoured core ends.

FIG. 6d shows an embodiment of a bobbin that is hinged but not split.

FIG. 7a shows an embodiment of an automation fixture.

FIG. 7b shows an embodiment of a case guide.

FIG. 7c shows an embodiment of a case feed slide.

FIG. 7d shows an embodiment of a case feed assembly.

FIG. 7e shows an embodiment of a case release slide.

FIG. 7f shows an embodiment of a case sort paddle.

FIG. 8 is an exemplary flowchart of phases of operation for a case annealer.

FIG. 9a shows modules in an embodiment of a case annealer.

FIG. 9b shows a manufacturing technique for an embodiment of a case annealer.

### DRAWINGS—REFERENCE NUMERALS

100—Induction Head
101—Controller
102—Hardware User Interface
104—Inverter
105—Regulator
106—Power Supply
107—Annealing Chamber
108—Internal Sensors
109—Data Unit
110—Hardware I/O Unit
111—Cartridge Case
112—Computer
113—External Sensors
114—Servo Controller
115—Enclosure
116—Simple Automation Machine
117—Collection Bin
120—Analysis Software
201—Magnetic Core
202—Split Hinged Bobbin
203—Electrical Conductor
204—Magnetic Core Ends
206—End Gap
208—Angle
211—Wire Groove
212—Magnetic Core Groove
213—Bobbin Hinge
220—Manufacturing Jig
221—Jig Hole
222—Jig Groove
223—Adhesive
231—Airflow Barrier
232—Head Support
233—Head Locating Pillar
234—Air
241—Barrier Tube
242—Airflow Baffle
302—Alternating Magnetic Flux
308—Left Mechanical Force
310—Right Mechanical Force
401—Discrete Element (Magnetic Region)
402—Discrete Thermal Resistance
403—Discrete Specific Heat
404—Discrete Heat Source
405—Thick Core Model
406—Thin Core Model
415—Thick Core Center
416—Thin Core Center
601—Spacer
611—Slit
641—Contour
700—Automation Fixture
701—Fixture Mount
702—Fixture Pillar
703—Fixture Upper Arm
704—Fixture Lower Arm
705—Fixture Adjustment Knob
710—Case Guide
711—Guide Tube
712—Guide Collet
713—Guide Bracket
714—Case Release Cutout
715—Guide Bracket Bevels
717—Shielding Gas Inlet
721—Case Feed Slide
722—Feed Groove
723—Feed Block
724—Feed Hole
725—Feed Servo
730—Case Feed Assembly
731—Feed Brace
732—Feed Tube Locator
733—Feed Tube Locator Slot
734—Feed Tube Locator Knob
735—Feed Tube
741—Case Release Slide
742—Release Slide Groove
743—Release Slide Servo
751—Case Sort Paddle
752—Sort Pivot Rod
754—Sort Servo
801—Prepare Phase
803—Feed Phase
805—Anneal Phase
807—Analysis Phase
809—Sort/Release Phase
821—Verify Prep
822—Verify Feed
823—Verify OK
830—Abort
901—Slot
910—Inner Structure
912—Outer Structure
914—Conductive Tape

### Detailed Description of the Invention

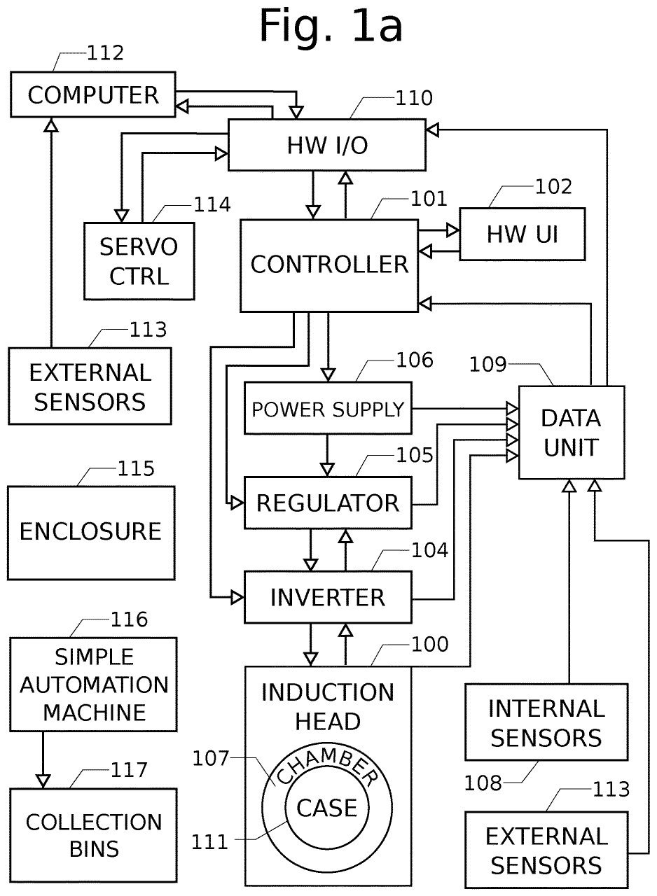

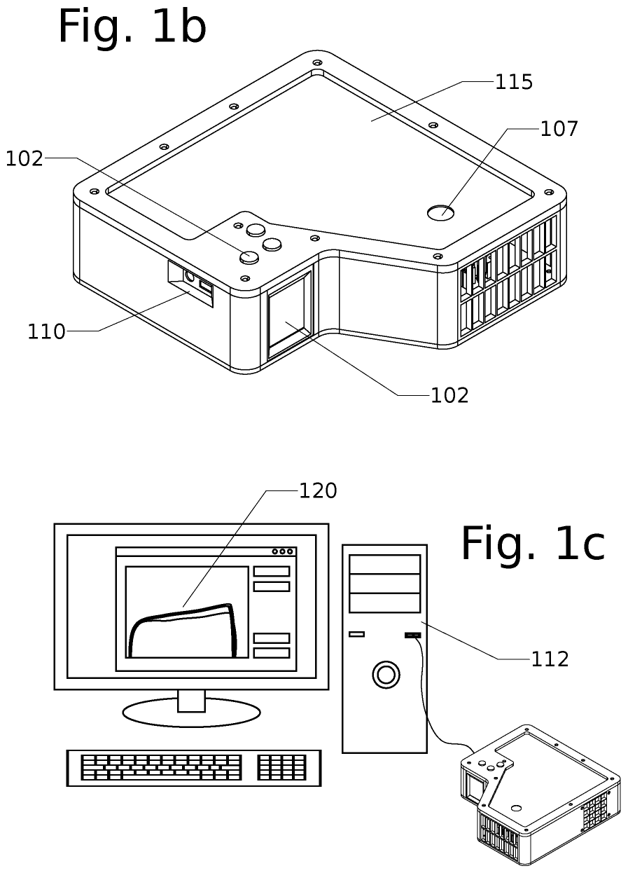

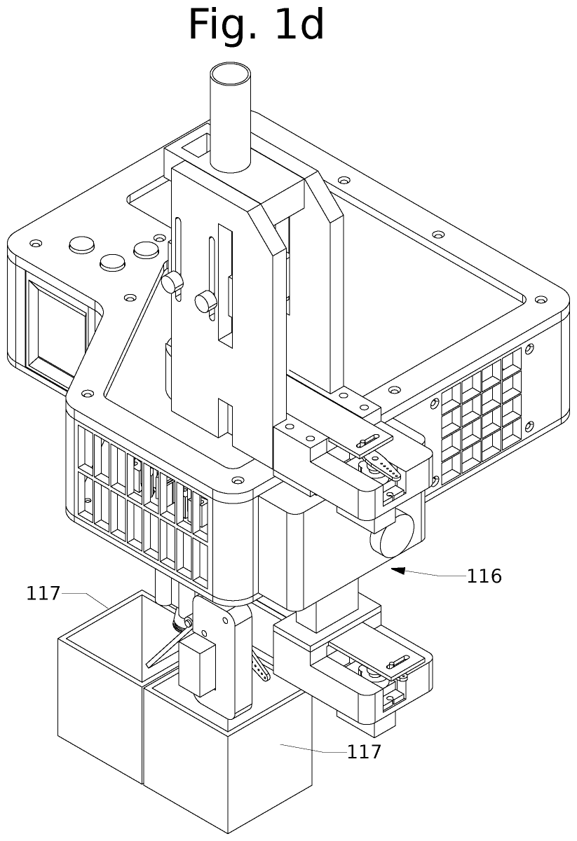

### Description—FIG. 1, Overview

FIG. 1a is an exemplary block diagram of modules that form an embodiment of a system for annealing cartridge cases. Some embodiments of the system may be modular to facilitate the manufacturing of different models from a shared inventory. In some embodiments this may allow the user to add or change functionality by adding or replacing modules. However, not every module described must be replaceable by the user.

In one embodiment an ammunition cartridge case 111 is annealed within an annealing chamber 107. An alternating magnetic flux passes through the annealing chamber 107 to induce the electric currents into the case that heat the case. The position of the case 111 within the chamber 107 determines which area of the case is heated. The annealing chamber is part of a larger unit called an induction head 100.

For clarity, the term induction head 100 may describe any module that receives alternating current and uses it to generate a field of alternating magnetic flux to anneal cartridge cases. The induction head 100 may also comprise additional elements such as bobbins, air baffles, and sensors. In some embodiments, when an induction head 100 is changed some of the additional elements may also be changed.

Since the way an induction head can generate flux is not limited, the annealing chamber 107 can be described as the area of the induction head 100 where annealing occurs. The method by which the case 111 is fed into and released out of the annealing chamber 107 depends on the embodiment of the system. Some embodiments may use manual methods while other embodiments may use automatic methods.

The user may communicate with a controller 101 through a hardware user interface (HWUI) 102. The HWUI may comprise buttons, keyboards, and/or displays. The user may communicate with the controller 101 using a computer 112 and a hardware input/output unit 110 (HWIO). The controller 101 may be a processor or a modular unit. On some embodiments, one method of communication with a controller may be omitted.

The controller 101 may send signals to a power supply 106, a regulator 105, and an inverter 104. The power supply 106 may supply power to the regulator 105. The regulator 105 may supply regulated power to the inverter 104. The regulator 105 and inverter 104 may use a feedback loop to facilitate power regulation. The inverter 104 may supply alternating electrical current to an induction head 100. The inverter 104 and head 100 may also use a feedback loop.

An automation machine (AM) 116 may be used to automate the feeding, releasing, and/or sorting actions of a case annealer. Cases 111 may be released by the AM 116 into one of a plurality of collection bins 117. On some embodiments the AM 116 may not be included.

A data unit 109 may collect data from the supply 106, the regulator 105, the inverter 104, and/or the head 100. The data unit 109 may also collect data from internal sensors 108 and/or external sensors 113 if present. Data from the data unit 109 may be sent to the controller 101. Data from the data unit 109 may also be sent to the HWIO unit 110.

A HWIO unit 110 may allow a case annealer to interface with external devices. For example, a servo controller 114 may interface with the controller 101 through the HWIO unit 110. The data unit 109 may send data directly to the computer 112 through the HWIO unit 110. In an exemplary embodiment the HWIO unit 110 has a USB port and a 3.5 mm jack.

A case annealer may use an enclosure 115 to house some or all of its modules. In an exemplary embodiment the enclosure 115 houses all modules of a case annealer.

FIG. 1b shows an exemplary embodiment of a case annealer. In this embodiment the HWIO unit 110 comprises a USB port for interfacing with the computer 112 and a 3.5 mm jack for interfacing with the servo controller 114. The HWUI 102 may comprise buttons and a TFT screen. The chamber 107 may be accessible via a tube (241) that runs through the top and bottom of the enclosure 115.

FIG. 1c shows an exemplary embodiment of a case annealer connected to the computer 112. In this embodiment analysis software 120 shows the user graphs of annealing data from multiple cases 111. The user can use these graphs to choose a set of cases 111 with similar physical properties. Alternatively an algorithm may process the annealing data, along with other data, to determine which cases 111 are most similar.

FIG. 1d shows an exemplary embodiment of a case annealer with the AM 116 attached. Two bins 117 are placed below the AM to facilitate the sorting of cases 111 according to annealing data and other data. A group of cases 111 with similar physical properties will shoot more precisely, and this is why sorting cases 111 based on annealing and other data may improve shooting precision.

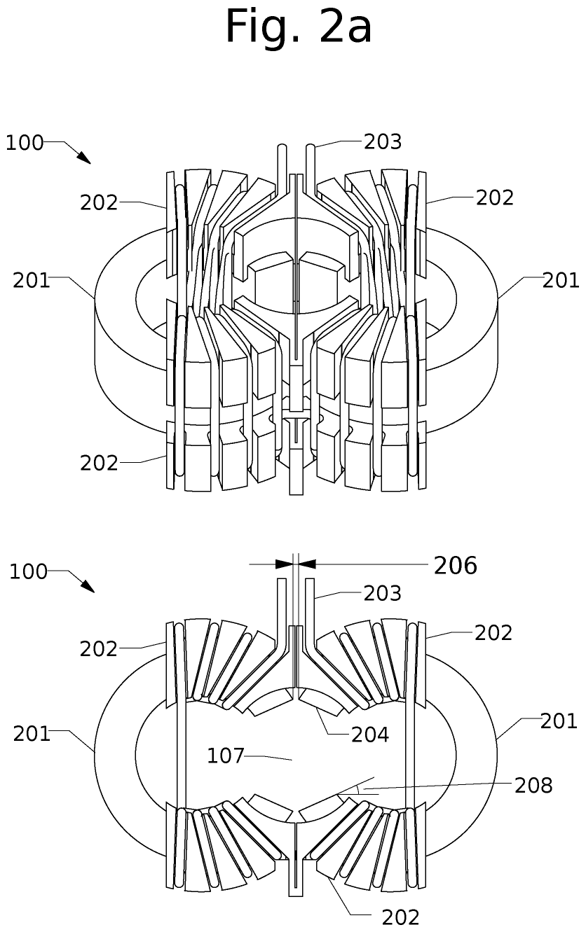

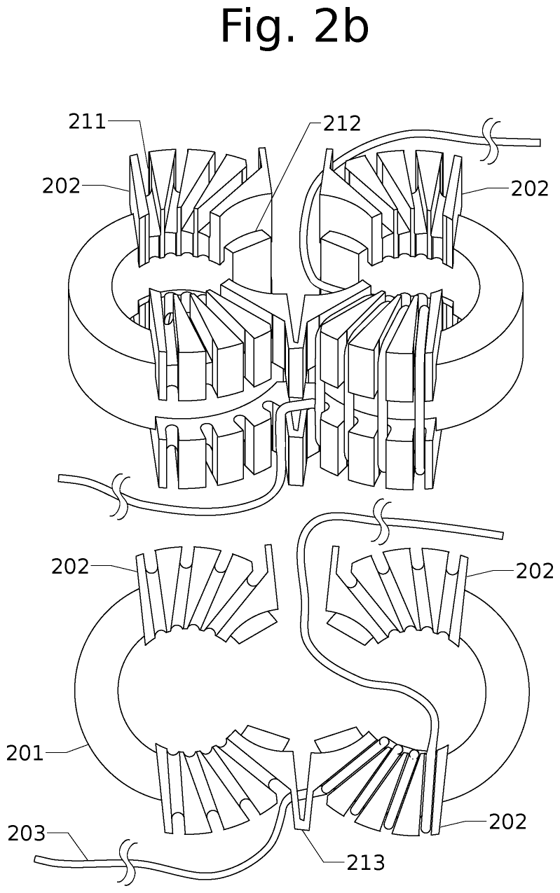

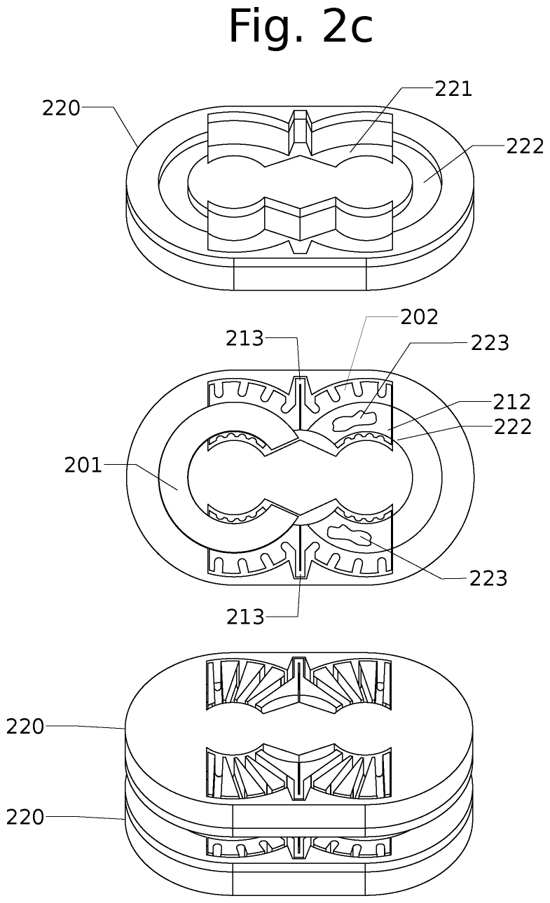

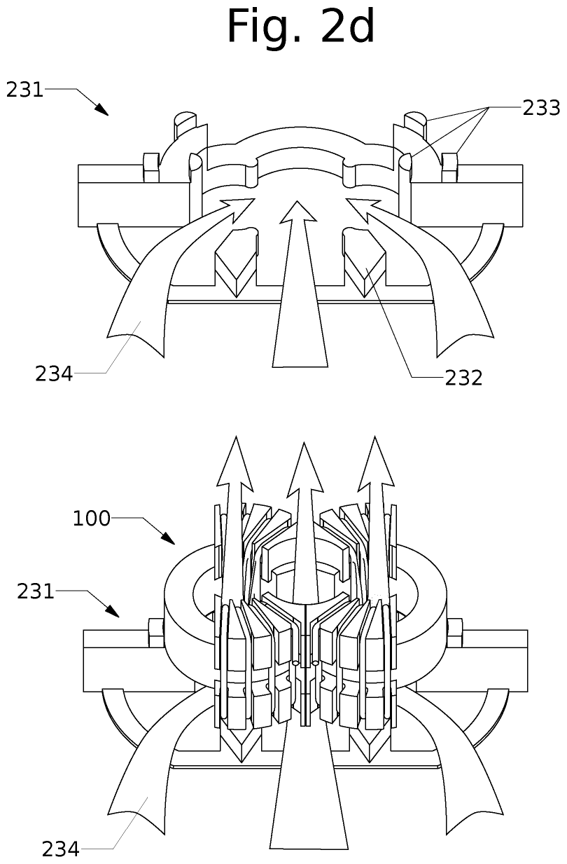

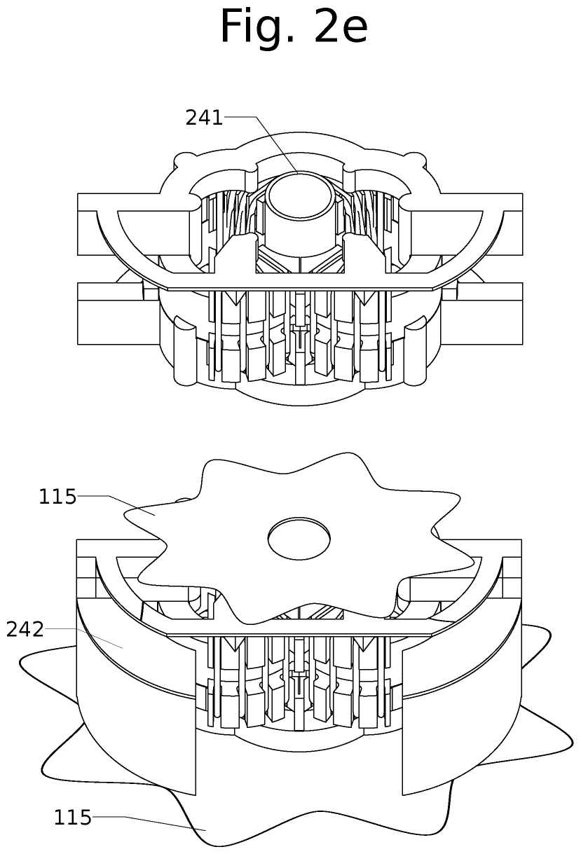

### Description—FIG. 2, Induction Head

FIG. 2a shows an exemplary embodiment of an induction head 100 comprising two magnetic cores 201, a split hinged bobbin 202, and an electrical conductor 203. Each magnetic core 201 has two magnetic core ends 204. In this embodiment the cores 201 are in the shape of cut toroids but other shapes may be used. The cores 201 are made of ferrite in this embodiment but any suitable magnetic material may be used.

The four ends 204 of the cores 201 are arranged symmetrically around an empty area of the induction head 100 called the annealing chamber 107. In this exemplary embodiment the four ends 204 are facing each other but are not touching. There is an end gap 206 between the magnetic core ends 204. The ends 204 are cut at an angle 208.

The conductor 203 is wound around the bobbin 202 and the cores 201. The conductor 203 in this embodiment is Litz wire but any suitable conductor may be used.

FIG. 2b shows an exemplary embodiment of the bobbin 202 attached to the cores 201. The bobbin 202 comprises a hinge 213 that allows the head 100 to separate so the conductor 203 can be wound more easily. The bobbin 202 may comprise a plurality of wire grooves 211 that hold one or more windings of the conductor 203. Each section of the bobbin 202 may comprise a magnetic core groove 212 that helps to center each section of the bobbin on the core 201.

FIG. 2c shows an exemplary embodiment of a manufacturing jig 220. The jig 220 comprises a pair of jig holes 221 into which sections of the split hinged bobbin 202 are inserted. The manufacturing jig 220 comprises a pair of jig grooves 222 which align with magnetic core grooves 212. During manufacture an adhesive 223 may be applied between the magnetic cores 201 and the bobbin 202. The hinge 213 may be left intact between sections of the bobbin 202 during manufacture and then removed on one side of the head 100 to enable the head to open.

FIG. 2d shows an exemplary embodiment of an airflow barrier 231. The barrier 231 may allow air 234 to flow from one side of the head 100 into its center while blocking most of the air from flowing out the other side of the head. The barrier 231 may direct air 234 through the center of the head 100. The barrier 231 may comprise a pair of head supports 232 which support the head 100 by the bobbin 202. The barrier 231 may also comprise a plurality of head locating pillars 233 which help the head stay in place.

FIG. 2e shows two airflow barriers 231 in an exemplary embodiment of a case annealer. A barrier tube 241 may be placed in the chamber 107. The tube 241 may extend from the bottom to the top of the enclosure 115 of a cartridge case annealing unit, which is cutaway in this view. The tube 241 prevents the air that cools the head 100 from cooling the case 111. An airflow baffle 242 may also be used to direct air around the outside coils of the head 100.

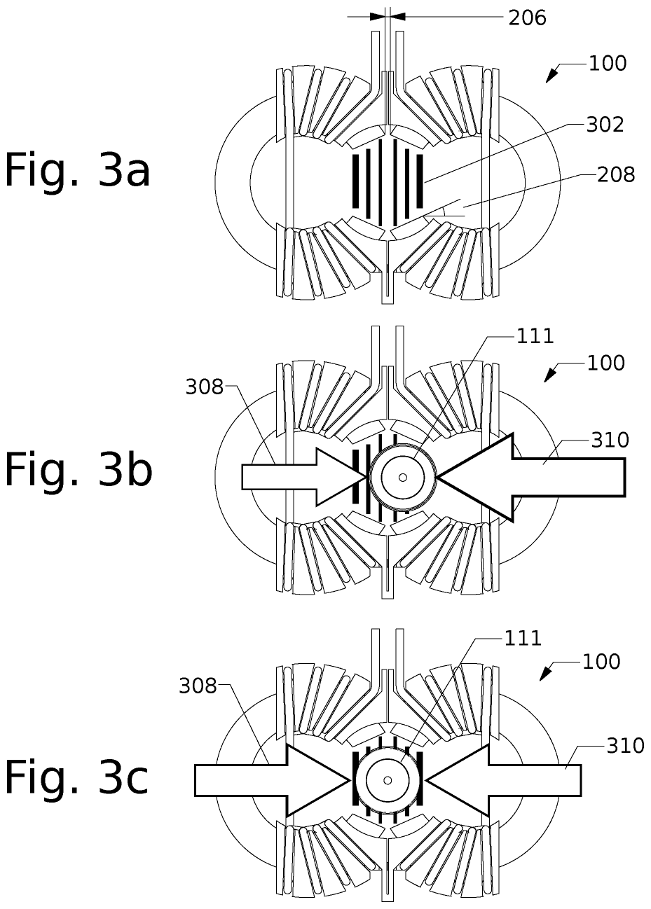

### Operation—FIG. 3, Induction Head, Centralizing Flux

FIGS. 3a, 3b, and 3c illustrate how an embodiment of an induction head 100 centers the case 111 during operation.

FIG. 3a shows the intensity of alternating magnetic flux 302 in the chamber 107 at the center of an induction head 100. The intensity of the flux 302 is stronger near the edges of the chamber than in the center and is indicated by thicker lines. The end gap 206 between the magnetic core ends 204 provides a region of lower flux intensity in the center of the chamber. Cutting the ends 204 at an angle 208 helps to strengthen the flux 302 near the edges of the chamber 107.

FIG. 3b shows the forces that center an off-center case 111 during operation. As the flux 302 alternates it induces electrical eddy currents in the case 111. According to Lenz's law these eddy currents create magnetic fields of flux that oppose the change in flux. A left mechanical force 308 comes from the left core 201 and a right mechanical force 310 comes from the right core 201.

The forces 308 and 310 are proportional to flux intensity. In FIG. 3b the case is closer to the right core 201 so the right force 310 is stronger than the left force 308. Therefore the centralizing net force will push or move the case 111 closer to center if the case is off center. A centered case will remain centered during annealing.

FIG. 3c shows that when the case 111 is in the center of the chamber 107 the left force 308 equals the right force 310. The equalized forces ensure that a centered case 111 remains secure in the center of the chamber during annealing.

For clarity, magnetic forces perpendicular to the forces shown have been omitted. Since the force imparted to the case 111 depends on flux intensity, it should be evident that a case which is closer to a magnetic core will experience a greater force. The result is a centralizing magnetic field.

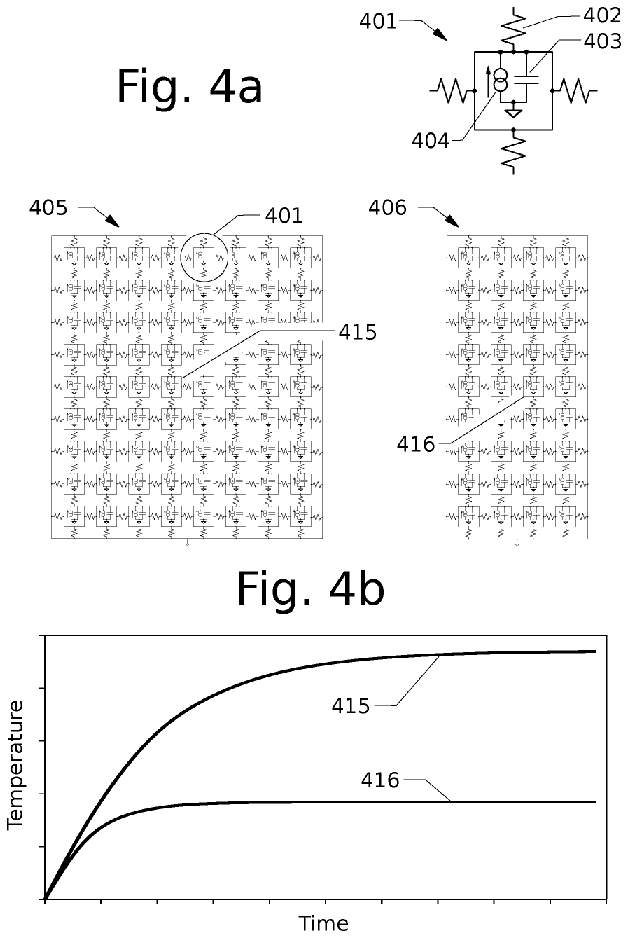

### Operation—FIG. 4, Induction Head, Cooling

FIGS. 4a and 4b illustrate a novel thermal benefit of an embodiment of an induction head 100 during operation using finite element analysis. During operation the magnetic cores 201 are heated by the alternating magnetic flux field 302 that heats the case 111. The design of the head 100 dissipates this heat faster than traditional designs.

Traditional head designs use a large magnetic core while this embodiment of an induction head 100 uses a plurality of small magnetic cores. Opting for small cores over a large core is not intuitive. Standard engineering practice is to increase core size as much as possible because it decreases magnetic flux density and allows more power transfer for a given frequency. The benefit of the design of this embodiment over traditional designs will become apparent from the analysis.

FIG. 4a shows the model used to compare the operating temperature at the center of the cores 201 with a traditional magnetic core. This model uses finite element analysis where a magnetic core is modeled as multiple small magnetic regions called ‘discrete elements’. Finite element analysis is used because it is problematic to measure the temperature inside a magnetic core during operation.

A discrete element 401 represents a region inside a magnetic core. Each discrete element 401 has a discrete thermal resistance 402 modeled by a resistor, a discrete specific heat 403 modeled by a capacitance, and a discrete heat source 404 modeled by a current source.

A thick core model 405 with area A is formed from an 8×9 grid of magnetic regions 401 and its center temperature is measured at point 415. A thin core model 406 with area A/2 is formed from an 4×9 grid of magnetic regions 401 and its center temperature is measured at point 416.

An approximately square shape was chosen for the thick core model 405 to match common C and U core geometries available as ferrite magnetic cores. The outside of both models 405 and 406 are held at a temperature of zero to simulate equal cooling at the surface.

The center temperatures of the two models at points 415 and 416 are given in FIG. 4b. According to this model the center temperature of the thin core 416 is less than half (0.408) of the center temperature of the thick core 415 during the application of an equal flux density. A model comparing an 8×18 to 16×18 array of discrete elements 401 yielded an even greater temperature decrease of 0.392.

This suggests that replacing the thick core 405 of cross sectional area A with two thin cores 406 of cross sectional area A/2 can reduce the temperature gradient between the center and surface of the core by approximately 60 percent.

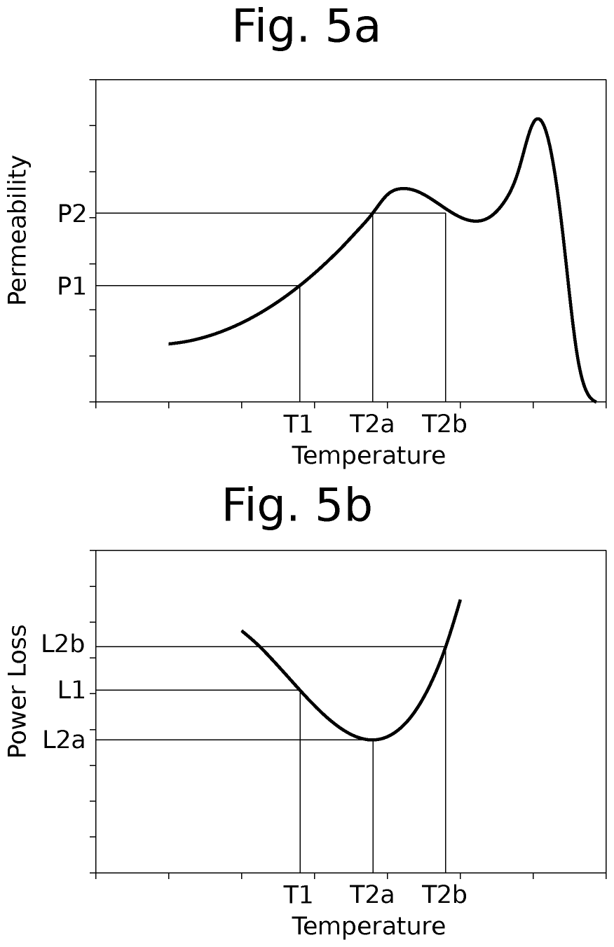

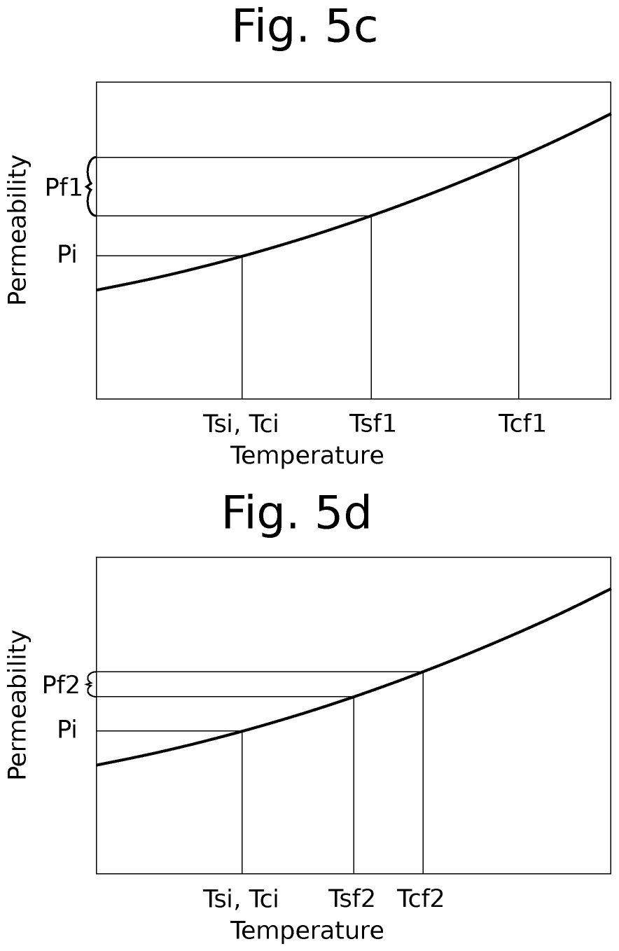

### Operation—FIG. 5, Induction Head, Data Acquisition

FIGS. 5a, 5b, 5c, and 5d demonstrate how novel properties of the induction head 100 enable a case annealer to better estimate the physical properties of the cartridge case 111 from annealing data during operation.

FIGS. 5a and 5b illustrate how a lower temperature in the induction head 100 improves the consistency of annealing data. Magnetic materials such as ferrite and iron have different properties depending upon their temperature. For example FIG. 5a is a graph of permeability versus temperature for an exemplary material used to make the magnetic cores 201. FIG. 5b is a graph of power loss versus temperature for the same material.

At lower temperatures a measured permeability may reliably indicate core temperature. For example, permeability P1 corresponds to core temperature T1 according to the graph in FIG. 5a. Temperature T1 can then be used to estimate power loss L1 from the graph in FIG. 5b.

At higher temperatures a measured permeability P2 may correspond to temperature T2a or T2b. Both of temperatures yield different power loss estimates which makes it difficult to know how much power the cartridge case 111 is absorbing.

Accurately estimating core temperature, permeability, and loss improves annealing data consistency because it helps to determine which data is a result of the induction head 100 and which data is a result of the case 111.

The lower temperature in the magnetic cores 201 of the head 100 also improve the quality of annealing data gathered during operation.

FIGS. 5c and 5d illustrate a novel analytical advantage of an induction head 100 which has a smaller temperature gradient between the core center and the core surface than in traditional designs. The reduced temperature gradient between the center and surface of the magnetic cores 201 minimizes the effect of nonlinear permeability and nonlinear loss on annealing data.

FIG. 5c shows an exemplary initial core temperature at the surface Tsi and center Tci of the thick core model 405. The initial permeability Pi accurately predicts core temperature because there is no temperature gradient between the center and surface of the magnetic core. After annealing the final core temperature Tsf1 and center temperature Tcf1 have separated as predicted in FIG. 4 because the center cools less quickly than the surface.

FIG. 5d shows an exemplary initial core temperature at the surface Tsi and center Tci of the thin core model 406 before and after annealing. The temperature gradient is reduced by approximately 60 percent as predicted from FIG. 4 which reduces the range of permeability Pf2 that will be detected and makes it easier to compensate for temperature rise with accuracy.

During operation the temperature gradients in the magnetic cores 201 depend on unpredictable factors comprising the number and type of cases 111 a user has annealed recently, the ambient temperature, and the time taken between annealing cases.

The cores 201 used in an embodiment of an induction head 100 reduce the effect of these unpredictable factors on annealing data and enable the user to detect the physical properties of cases 111 with higher precision. A case annealer may also facilitate the gathering of other data to be used in conjunction with annealing data from an induction head 100.

Further, this exemplary embodiment of a case annealer keeps the induction head 100 cool without the use a coolant circulating system.

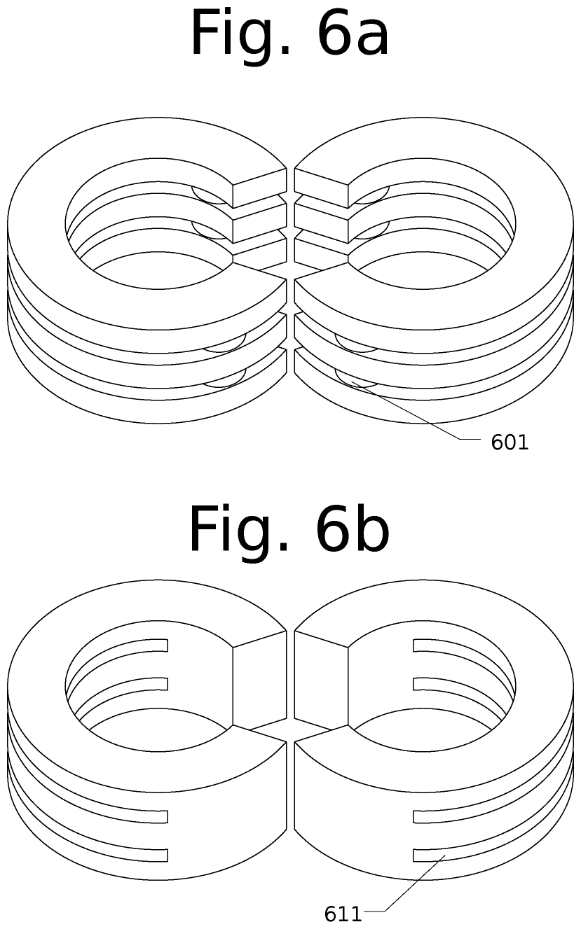

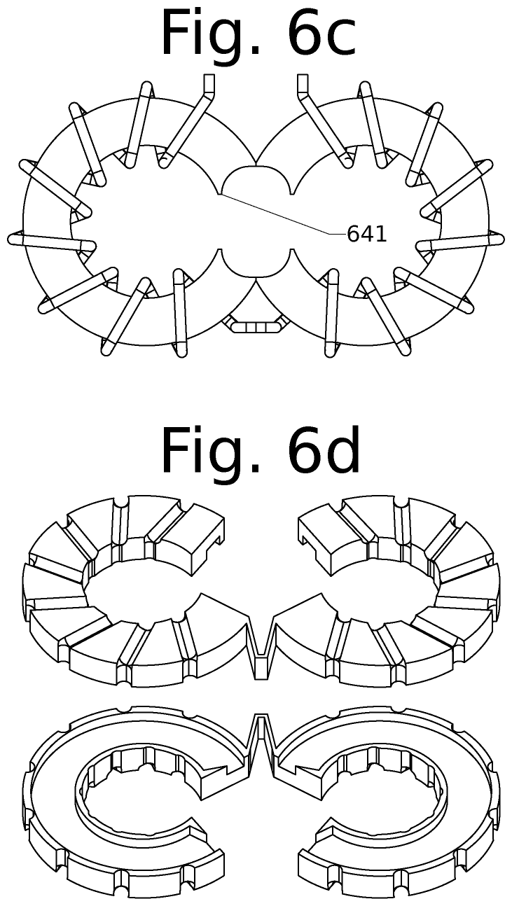

### Description—FIG. 6, Induction Head, Alternative Embodiments

Many variations on the induction head 100 are possible. The shape of the magnetic cores 201 can be polygonal and multiple magnetic cores may be used. The ends 204 of the magnetic cores can comprise bevels and do not need to be radially cut. There does not need to be a gap 206 between the ends of each magnetic core.

The conductor 203 may comprise one or multiple filaments. There may be one or more conductors 203 on the induction head 100 and conductors may be tapped in one or more locations. For example the conductor 203 may comprise a center tap at its midpoint to allow the use of different inverter 104 circuit types. In another embodiment a main conductor provides power and an auxiliary conductor provides feedback.

It is also possible to build the induction head 100 without using the bobbin 202.

FIG. 6a shows an arrangement of six magnetic cores separated by spacers 601 that may be used in place of the magnetic cores 201 shown in FIG. 2. The heat dissipation of this embodiment is increased at the expense of a higher flux density.

FIG. 6b shows two magnetic cores that have slits 611 cut in their sides to increase cooling in a similar fashion.

FIG. 6c shows an embodiment of an induction head where the end gap 206 is not present. In this embodiment a contour 641 on the magnetic core ends may sufficiently shape the flux. The conductor 203 may be made from any suitable material including a water cooled tube.

FIG. 6d shows an embodiment of a bobbin that uses a conventional wiring pattern. In this embodiment each half of the bobbin is a single piece.

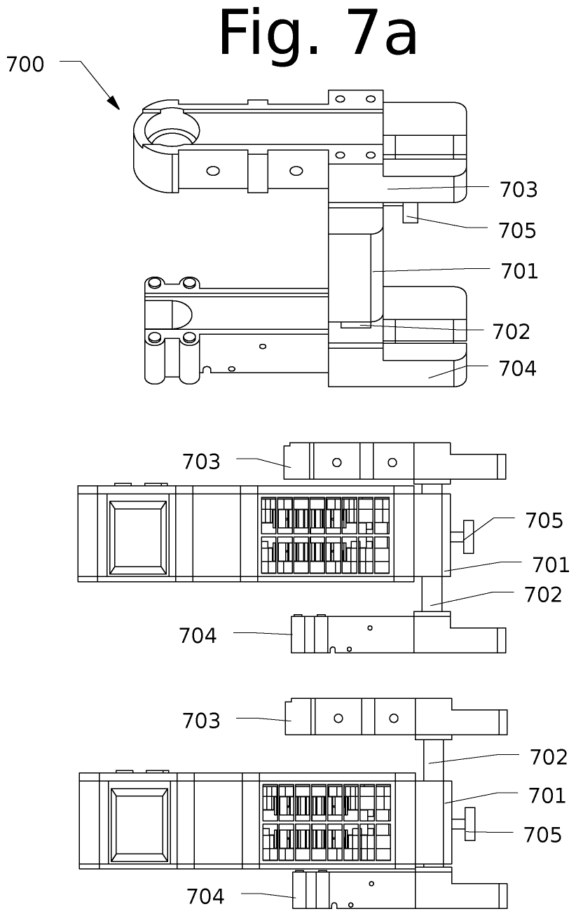

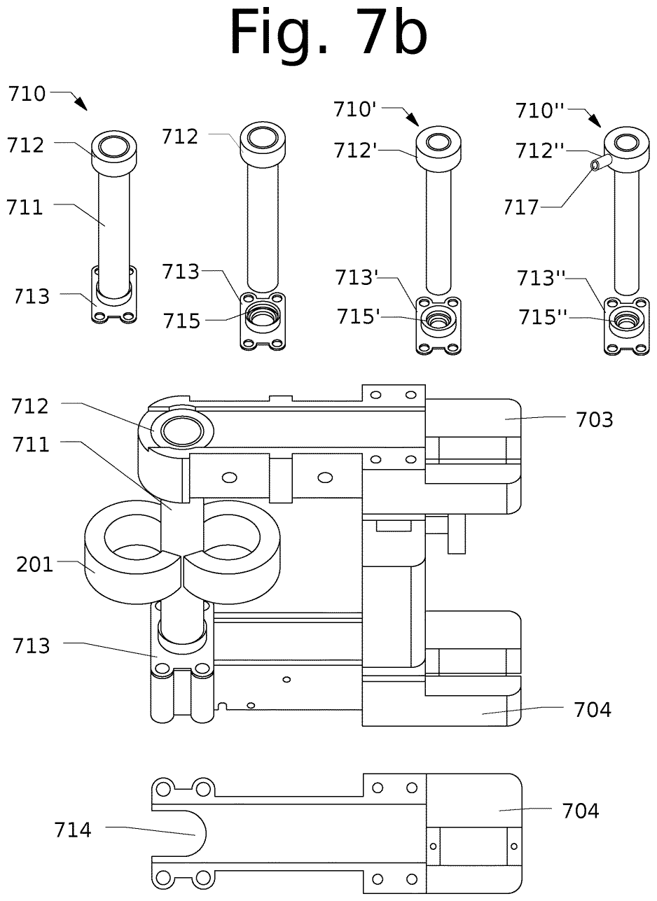

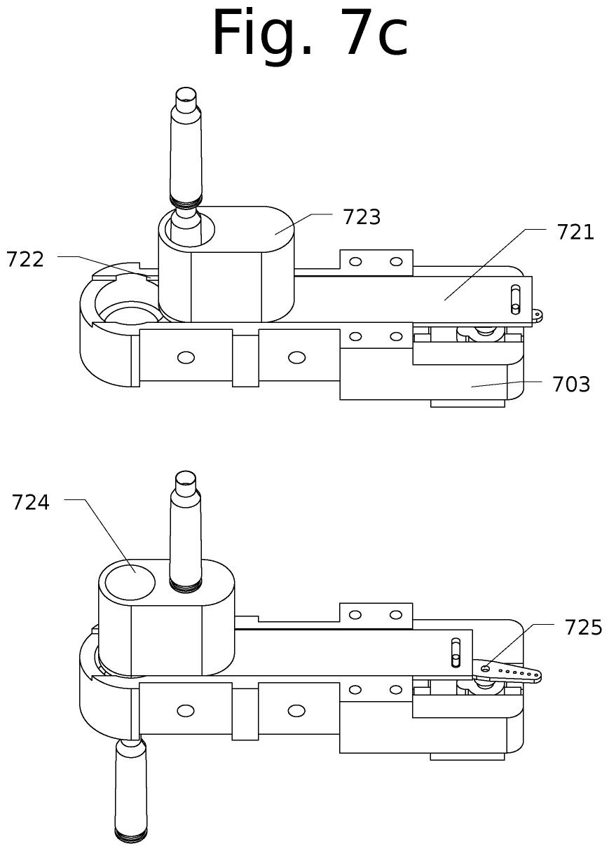

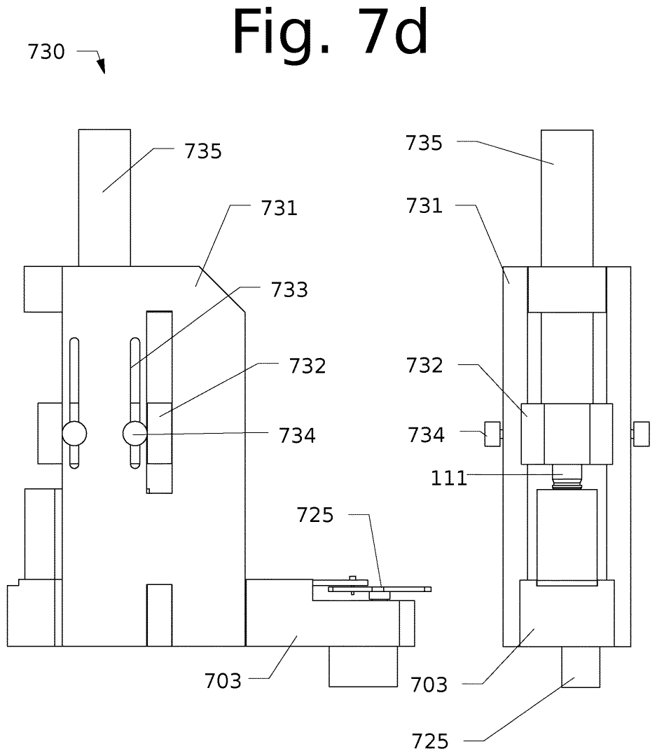

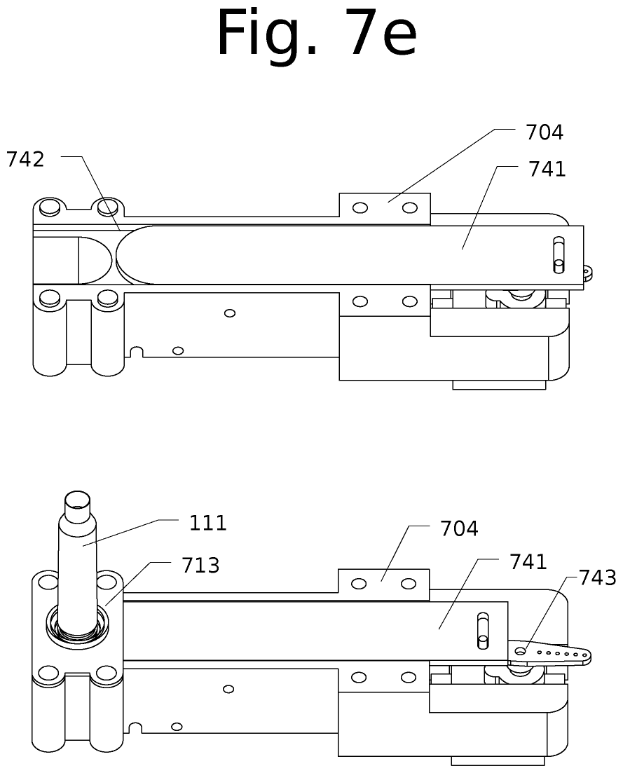

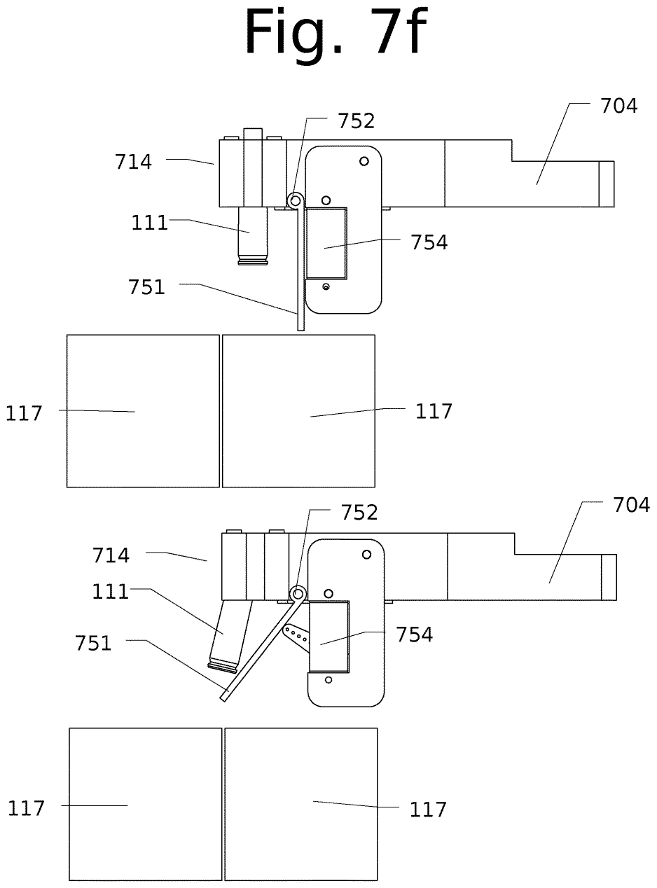

### Description—FIG. 7, Automation Machine (AM)

Unlike other automation machines, the automation machine 116 of this embodiment does not use a cartridge holder and does not require a separate bushing for every diameter of case. This allows less stringent manufacturing tolerances. The AM 116 also makes no significant contact with the case 111 during or after annealing which reduces thermal transfer. This enables less expensive materials to be used. Some embodiments of the AM 116 provide for the use of shielding gas during annealing.

FIG. 7a shows an automation fixture 700 comprising a fixture mount 701 that attaches to the enclosure 115. A fixture pillar 702 may be inserted into a fixture mount 701. A fixture upper arm 703 and a fixture lower arm 704 may attach to the pillar 702. The mount 701 comprises a fixture adjustment knob 705.

The fixture 700 allows the user to adjust the height of the AM 116 in relation to the chamber 107. This in turn determines which part of the case 111 will be annealed in the chamber 107.

FIG. 7b shows a case guide 710 that comprises a guide tube 711, a guide collet 712, and a guide bracket 713. The collet 712 positions the guide 710 in the upper arm 703. The bracket 713 aligns the guide 710 with a case release cutout 714 in the lower arm 704. The bracket 713 may comprise bevels 715. The guide 710 passes through the chamber 107 formed by the cores 201.

Different sizes of case guide 710′ may be interchanged depending on the application and the case 111 being annealed. One embodiment of a case guide 710″ has a gas inlet 717 that allows a shielding gas such as carbon dioxide to surround the case 111. The use of a shielding gas enables faster annealing at higher temperatures by reducing the rate of oxidization.

The guide 710 ensures the case 111 can pass through the center of the annealing chamber 107 without touching other items that would impede its movement. The guide also provides electrical insulation between the voltages of the induction head 100 and a user, as may be required by safety standards. The guide 710 does not hold or secure the case. The guide 710 does not need to secure or touch the case during annealing because the flux 302 produced by the head 100 centers the case.

The minimum inner diameters of the tube 711 and the bracket 713 are larger than the maximum outer diameter of the case 111. One guide 710 may support cases 111 of multiple sizes and calibers. Guides 710 may be interchanged or replaced.

FIG. 7c shows a case feed slide 721 positioned within a feed groove 722 in the upper arm 703. A feed block 723 with a feed hole 724 attaches to the feed slide 721. A feed servo 725 is mounted in the upper arm 703.

FIG. 7d shows how a feed tube 735 is positioned relative to the feed block 723. Two feed braces 731 attach to the upper arm 703. The braces 731 abut to a feed tube locator 732. The braces 731 each contain two feed tube locator slots 733. A feed tube locator knob 734 secures the locator 732 to the braces 731. The feed tube 735 inserts into the locator 732.

FIG. 7e shows a case release slide 741 positioned within a release slide groove 742 in the lower arm 704. A release slide servo 743 is mounted to the lower arm 704.

FIG. 7f shows a case sort paddle 751 attached to a sort pivot rod 752 in the lower arm 704. A sort servo 754 is mounted to the lower arm 704. A first collection bin 117 is placed directly below the case release cutout 714. A second collection bin 117 is placed next to the first collection bin. The release cutout 714 allows the sort paddle 751 to operate at a flatter angle without causing the case 111 to bind against the bracket 713.

### Operation—FIG. 7, Automation Machine

A user may adjust the height of the AM 116 with the knob 705 so that the case 111 is at the desired height in the chamber 107. The guide 710 and bracket 713 are chosen so the case 111 lands vertically without the risk of falling into the sides of the guide 710 and does not bind against the bracket 713 during release.

The feed tube 735 is filled with cases 111. The release slide 741 is positioned so that the case rests on the release slide rather than falling through the release cutout 714. The locator 732 is positioned one case length above the upper arm 703.

The feed servo 725 moves the feed slide 721 so that the hole 724 is under the feed tube 735. This allows a case 111 to drop into the hole 724.

The feed servo 725 then moves the feed slide 721 so that the hole 724 is above the chamber 107. The case 111 drops from the hole 724 into the guide 710 into the annealing chamber 107. Meanwhile the feed block 723 keeps cases from falling out of the feed tube 735.

During annealing the case 111 rests on the release slide 741. The alternating flux of the induction head 100 imparts a centralizing magnetic force that pushes the case 111 towards the center of the chamber 107 if it is off center. If the case is centered at the start of annealing it will remain centered.

After annealing, the sort servo 754 positions the sort paddle 751 so the case 111 will either fall into the first bin 117 or be deflected into the second bin 117. The release slide servo 743 moves the release slide 741 to allow the case 111 to fall out of the chamber 107 and into the appropriate bin 117.

### Alternative Embodiments—Automation Machine

In an exemplary embodiment the height adjustment is made with the fixture adjustment knob 705 but alternatively it could be made with spacers, bushings, or using a mechanical actuator. The guide 710 may be made of a single piece or of multiple pieces that can be disassembled.

The feed tube 735 may be replaced with any item that organizes cases vertically. In the field of reloading it is common to use a device called a ‘case feeder’ which organizes cases into a vertical stack as suggested in FIG. 7c. Case feeders stack cases vertically into tubes similar to the feed tube 735, and a feed block 723 may be designed to accept these tubes.

In some embodiments a shroud which covers a portion of the AM 116 moves shielding gas through the guide tube 711 without the use of inlet 717.

In this exemplary embodiment the feed slide 721, the release slide 741, and the sort paddle 751 are moved by servo motors but alternatively they may be operated by another mechanical device or manually.

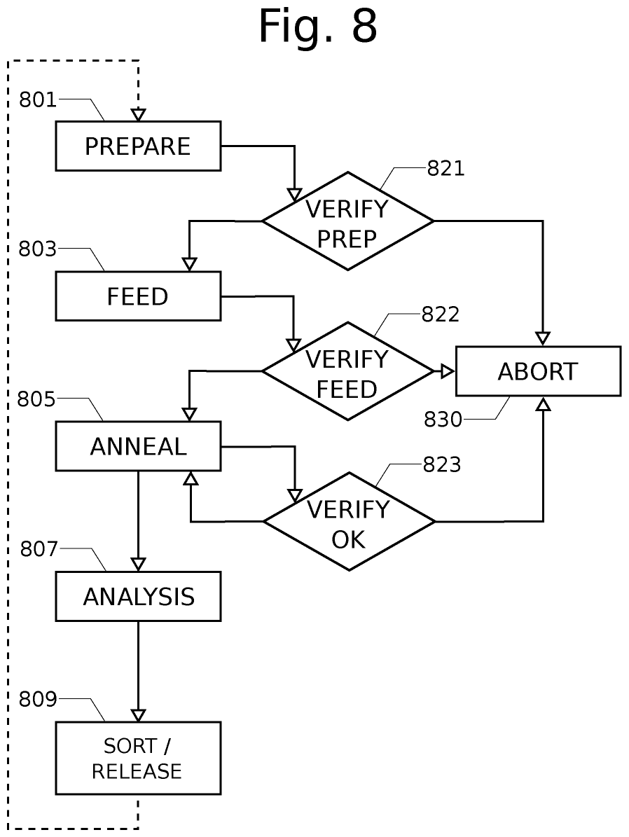

### Operation—FIG. 8, Annealing Process Flow

FIG. 8 lists an exemplary flowchart of phases of operation for a case annealer. The phases of operation comprise a prepare phase 801, a feed phase 803, an anneal phase 805, an analysis phase 807, and a sort/release phase 809.

It should be obvious to someone having ordinary experience in process control that the phases in FIG. 8 may be combined, changed, skipped, and/or omitted. A case annealer may be updated to enable different phases and additional functionality, and/or may be user programmed. For instance, some embodiments may incorporate the analysis phase 807 into the anneal phase 805.

A user may initiate a prepare phase 801 by pressing a button on the HWUI 102 or through the computer 112. The controller 101 may then enable the supply 106 and regulator 105 to provide a low power alternating electric current to the head 100 through the inverter 104.

Data from the data unit 109 may be checked to verify the annealing chamber 107 is empty and operating as expected in a verify prep 821 step. If the chamber 107 is not empty or if a problem is detected the process may be aborted 830. Otherwise the controller 101 may briefly increase power to the head 100 while the data unit 109 establishes a no-load baseline. The controller 101 may then return the power to a low level.

During a feed phase 803 the case 111 may be fed into the annealing chamber 107. The controller 101 may prompt the user to feed the case 111 manually, or activate the feed servo 725 on the AM 116.

After a case 111 is fed into the chamber 107 a verify feed step 822 may take place. The controller 101 may verify the case 111 was fed correctly and has the expected physical properties by comparing low power data to a standard. Data may not meet the standard if a case 111 is damaged, hot, or otherwise incorrectly loaded. If the controller receives unexpected data from the data unit 109 an error message may be displayed and/or the process may be aborted 830.

Data that is collected during the feed phase 803 and during other phases may come from any source and from any type of sensor. For example, sensors may track environmental data such as humidity or physical data such as the weight or dimension of the case 111. An optical camera and AI algorithm may ensure the case 111 is loaded correctly during the feed phase 803. The inclusion of data from multiple types of sensor may help in the analysis of data variance and enable greater precision.

During an anneal phase 805 a high power alternating magnetic flux may anneal the case 111. The amount of power supplied to the head 100 may be determined by settings in the controller 101 and/or the computer 112. The power delivered to the head 100 may be adjusted by the controller 101 during annealing to hold a desired data variable constant.

As the case 111 is annealed, the regulator 105 may prevent transient variations from causing an undesirable fluctuation in delivered power. The inverter 104 may adjust the frequency of power delivered to the head 100.

A data unit 109 may capture data from a plurality of sources comprising the head 100, inverter 104, regulator 105, supply 106, internal sensors 108, and external sensors 113. Internal sensors 108 and external sensors 113 may comprise infrared temperature sensors, infrared cameras, optical cameras, search coils, and other sensors. External sensors may be connected to the data unit 109 and/or directly to the computer 112.

Data from the data unit 109 may be checked during the anneal phase 805 to verify the annealing is proceeding as expected. A verify OK step 823 may abort 830 for conditions such as overcurrent, overheating, or other conditions. During normal operation an anneal phase 805 may continue until a predetermined time has elapsed and/or a data variable reaches a predetermined value.

During an analysis phase 807, data may be compared to standards in order to reach results. The data used is not limited to annealing data gathered from the head 100, but may include data from internal sensors 108 and external sensors 113.

The method of comparison may involve a software algorithm and/or user interaction. Graphs that include data and/or standards may be displayed and analyzed. Standards may come from a lookup table, from user entry, and/or from analyzing other cases 111.

Results may indicate whether annealing was successful, whether a case 111 met or exceeded a certain standard, how similar one case was to other cases, or provide other information to a user.

The method of comparison, the source of the standards, and the type of results may vary depending on the application or user preference. For instance, a user who shoots in close range self defense competitions may reload large quantities of ammunition and want to anneal as quickly as possible using automated comparison methods against pass/fail standards that weed out cartridge cases which are likely to fail. A user who shoots long range may want to analyze each case and compare it to other cases using graphs and standard deviation to find a group of cases with similar physical properties that will yield the most precision.

During a sort/release phase 809 a case 111 may be released into a bin 117 based on the result of an analysis phase 807. In an exemplary embodiment there are two bins 117. One bin is used for cases that exceeded a standard and the other for cases that failed.

In some embodiments there may only be one bin that all cases 111 are released into. In other embodiments there may be a plurality of bins 117 and the case 111 may be sorted into one of the bins based on the result of the analysis phase 117.

The release from the annealing chamber 107 may or may not be sudden. The release may be automated, or may require user intervention. An exemplary embodiment of the AM 116 uses the force of gravity to release the case 111 from the chamber. Other embodiments may use propellant such as compressed air, spring loaded devices, or other mechanical means.

After the sort/release phase 809 is complete the process may restart automatically.

### Alternative Embodiments

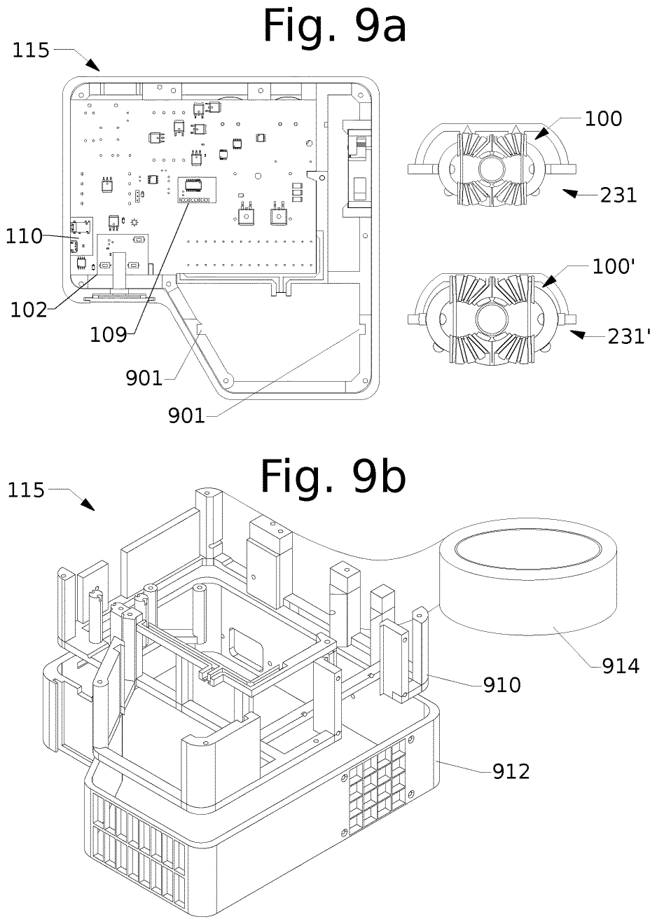

### Description—FIG. 9, Modules and Alternative Embodiments

An embodiment of a case annealer described herein may be a modular device with functional blocks that may be combined, exchanged, or omitted to provide customers with economical options that fit their needs. An embodiment of a case annealer may further also allow the user to write their own software/firmware to allow process and protocol customization.

FIG. 9a shows how an exemplary embodiment of a case annealer may be made in a modular way for the purpose of manufacturing different models. In this embodiment the enclosure 115 may have a pair of slots 901 which allow induction heads 100 and 100′ to be interchanged. The airflow barriers 231 and 231′ may have the same outer dimension.

In another embodiment modules such as the HWIO unit 110, data unit 109, HWUI 102, etc. may be interchanged and/or upgraded by the user in the same way a computer owner may upgrade their hard drive or RAM with a more powerful or more modern version.

Modules may be exchanged or omitted from a case annealer to match part availability and market needs. For example, one embodiment may exclude the HWUI 102 and be operable exclusively over the computer 112. Another embodiment may exclude the AM 116. Another embodiment may fully omit a HWUI 102, and be fully controlled by a computer 112.

Some embodiments of a case annealer may use multiple enclosures 115 to enable a user to safely exchange modules in a way that meets applicable safety and electromagnetic compatibility standards. For example, the induction head 100 may exist within an enclosure that is removable from the main unit. Alternatively, some embodiments may be sold in kit form and omit the enclosure 115 entirely.

Some embodiments of a case annealer may mix aspects of this disclosure with traditional annealer designs. For example, one embodiment may collect annealing data from an induction head 100 that uses a liquid cooled work coil.

FIG. 9b shows how an enclosure 115 may comprise shielding or shells as needed for EMI reduction. An exemplary embodiment of the enclosure 115 may contain an inner structure 910 and an outer structure 912. Both the inner structure 910 and outer structure 912 may be made of plastic. The inner structure 910 may be wrapped with a layer of conductive tape 914 to achieve EMI reduction. A top and bottom may be cut from a flat piece of sheet metal and contact the tape, enclosing the electronic components in a Faraday cage. This keeps manufacturing costs low and prevents customers from paying for an expensive and unnecessary metal enclosure.

A HWIO unit 110 may communicate in any manner available, even a protocol not yet invented. A HWIO unit 110 is not limited to the popular interfaces of today such as USB, WiFi, and optical. A HWIO unit 110 may control hardware devices directly using custom protocols. A case annealer may use firmware/software which may be updated by the user to ensure compatibility with future technology.

The modules of FIG. 1a may be grouped and renamed. For example, the supply 106, the regulator 105, and the inverter 104 may be manufactured as or referred to as a “controllable power supply”. The functionality of modules in FIG. 1a may also be distributed in alternative ways. For example, the functionality of the controller 101 and the data unit 109 may exist within the same physical microprocessor or be further spread between multiple processors.

### Conclusion, Ramifications, and Scope

From the aforementioned description several advantages of embodiments and certain aspects of embodiments become apparent.

There are certain details of the embodiments which would seem obvious to a person having ordinary skill in the arts, and are therefore not elaborated upon. For example storing local copies of data collected by the data unit within the control unit to enable access without an external computer, or exposing control variables within the control unit to a user via the external computer. Obvious extensions of aspects disclosed within this disclosure should be considered part of this disclosure.

Further, aspects of the embodiments in this disclosure may be used in other embodiments without departing from the spirit or essential characteristics of this disclosure.

Although many embodiments have been disclosed in detail herein, the scope of the embodiments should be determined by the claims rather than the examples of specific embodiments. The details of the embodiments herein are not intended as restrictive but exemplary.

What is claimed is:

1. An apparatus for annealing a cartridge case, comprising:
an electrical conductor configured to generate an alternating magnetic field from an alternating electrical current;
a data unit configured to capture at least one data point which is influenced by at least one physical property of the cartridge case; and
a processor operably coupled to the data unit;
wherein the processor is configured to determine a result through a comparison of the at least one data point and a standard.

2. The apparatus of claim 1, wherein the at least one data point is captured before the cartridge case has been annealed.

3. The apparatus of claim 2, wherein the result is determined before the cartridge case has been annealed.

4. The apparatus of claim 1, wherein the at least one data point is influenced by the alternating magnetic field.

5. The apparatus of claim 1, wherein the standard is based on at least one of a value stored in a memory, a user entry, and a previously captured data point.

6. The apparatus of claim 1, wherein the result is determined by generating a comparative visualization for user validation, wherein the comparative visualization comprises the at least one data point.

7. The apparatus of claim 1, further comprising a mechanical device operable to modify a clearance path between the cartridge case and an external location.

8. A method for annealing a cartridge case, comprising:
generating an alternating magnetic field by supplying an alternating electrical current to an electrical conductor;
capturing at least one data point which is influenced by at least one physical property of the cartridge case;
providing the at least one data point to a processor; and
determining a result through a comparison of the at least one data point and a standard according to a comparison protocol.

9. The method of claim 8, wherein at least a portion of the determining takes place on an external computer.

10. The method of claim 8, wherein the capturing of the at least one data point and the generating of the alternating magnetic field occur in any order, including concurrently and sequentially, and optionally are repeated one or more times.

11. The method of claim 8, further comprising using the at least one data point to create a future standard for use in at least one future process.

12. The method of claim 8, wherein a user may modify at least one of: the standard, the comparison protocol.

13. The method of claim 8, further comprising displaying a visual comparison between the at least one data point and the standard.

14. The method of claim 8, further comprising modifying a clearance path between the cartridge case and an external location based on the result.

15. A system for annealing a cartridge case, comprising:
an induction head comprising an electrical conductor configured to generate an alternating magnetic field from an alternating electrical current;
a data unit configured to capture at least one data point which is influenced by at least one physical property of the cartridge case; and
a processor configured to determine a result based on a comparison between the at least one data point and a standard;
wherein the processor is operably coupled to the data unit.

16. The system of claim 15, wherein the standard is adjusted in response to an expected physical property of the cartridge case, wherein the expected physical property is a predicted state of the at least one physical property of the cartridge case.

17. The system of claim 15, wherein the processor is configured to calculate a component of the at least one data point which is attributable to the at least one physical property of the cartridge case.

18. The system of claim 15, further comprising a display configured to show a visual representation of the at least one data point.

19. The system of claim 15, further comprising a hardware input/output unit operable to transfer the at least one data point to an external device.

20. The system of claim 15, further comprising a machine operable to sort the cartridge case into one of a plurality of bins according to the result.
